(19) United States
(12) Patent Application Publication
(10) Pub. No.: US 2003/0058017 A1
(43) Pub. Date: Mar. 27, 2003

(54) Alpha strike-insensitive latch design

(76) Inventor: Guy Harlan Humphrey, Fort Collins, CO (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 09/957,864

(22) Filed: Sep. 21, 2001

(51) Int. Cl. H03K 3/356

(52) U.S. Cl. 327/210

(57) ABSTRACT

A latch that is insensitive to alpha particle strikes. The latch comprises input circuitry that receives an input data value to be stored in the latch, a transfer gate that is closed when the input circuitry is driving the latch to store the received data value, and a feedback circuit that drives the latch when the transfer gate is opened and the input circuitry is no longer driving the latch. When the input circuitry is driving the latch, the strength of the input circuitry is sufficient to prevent an alpha strike error from occurring in the latch. When the input circuitry is not driving the latch, the transfer gate is opened and the feedback circuit generates a feedback signal that drives the latch with sufficient strength to prevent an alpha strike error from occurring.

### TECHNICAL FIELD OF THE INVENTION

The present invention generally relates to a latch design and, more particularly, to a latch that is designed to be insensitive to alpha particle strikes.

### BACKGROUND OF THE INVENTION

When designing latches in integrated circuits (ICs), it is known to design the latch so that it will be resistant to an alpha particle strike (hereinafter referred to as “alpha strike”). When an alpha strike occurs, the strike causes a current to be injected into a node, which can cause the voltage on the node to be pulled either higher or lower, depending on the polarity of the current. The change in the voltage on the node may result in the value stored in the latch being erroneously changed (i.e., from high to low or from low to high). Of course, this change in the latch value may cause a logic error to occur.

Generally, two different techniques are used to reduce or eliminate the possibility of an error being caused by an alpha strike. One technique is to have a large amount of capacitance built in to the latch design to prevent a node from quickly charging and discharging. By having a larger capacitance, the voltage on a node will change to a lesser extent over time with respect to the alpha strike current waveform, which is typically of short duration (e.g., on the order of picoseconds). Therefore, the greater the amount of capacitance, the less sensitive the latch will be to an alpha strike.

However, increasing the capacitance of the latch increases its size, which is undesirable because the latch then uses up more “real estate” on the IC chip. The trend in IC fabrication processes is to create smaller circuits with lower power supplies. This scaling down of the power supply results in the voltage difference between ground and the trip point of the latch inverter, and between the trip point of the latch inverter and the power supply, becoming smaller. Consequently, the amount of charge that must be generated by an alpha strike in order for the alpha strike to cause an error to occur has become smaller. To make matters worse, the alpha strike current component does not scale down with the scaling down of the power supply. Therefore, adding capacitance to a node to make the node resistant to alpha strikes is problematic, to say the least.

The other technique used to make a latch design resistant or insensitive to an alpha strike is to employ a strong feedback circuit that provides strong feedback through a large driver that is continuously driving every node so that if an alpha strike occurs, the strong feedback will overpower the energy associated with the injected alpha strike current. One of the problems caused by continuously providing a strong feedback is that it makes it more difficult to change the data in the latch when a new value is received at the input to the latch, i.e., the setup time of the latch is increased. Therefore, this technique results in a performance penalty.

Accordingly, a need exists for a latch design that is insensitive to alpha strikes and that can be employed in state-of-the-art IC fabrication techniques without incurring penalties in terms of increased setup times or area consumption.

### SUMMARY OF THE INVENTION

The present invention provides a latch that is insensitive to alpha particle strikes. The latch comprises input circuitry that receives an input data value to be stored in the latch, a transfer gate that is closed when the input circuitry is driving the latch to store the received data value, and a feedback circuit that drives the latch when the transfer gate is opened and the input circuitry is no longer driving the latch. When the input circuitry is driving the latch, the strength of the input circuitry is sufficient to prevent an alpha strike error from occurring in the latch. When the input circuitry is not driving the latch, the transfer gate is opened and the feedback circuit is turned on to generate a feedback signal that drives the latch with sufficient strength to prevent an alpha strike error from occurring.

The present invention also provides a method of storing data in a latch that renders the latch resistant to alpha strikes and prevents the stored data from being corrupted. The method comprises the steps of receiving an input data value to be stored in the latch, closing a transfer gate when the input data value to be stored in the latch is received at input circuitry of the latch, and opening the transfer gate once the input data value has been stored in the latch and turning on a feedback circuit to generate a feedback signal that drives the latch and renders the latch resistant to an alpha strike. When the transfer is closed, the input circuitry drives the latch with sufficient strength to prevent an alpha strike error from occurring in the latch. When the input circuitry is not driving the latch, the transfer gate is closed and the feedback circuit drives the latch with a feedback signal that prevents an alpha strike error from occurring.

These and other features and advantages of the present invention will become apparent from the following description, drawings and claims.

### BRIEF DESCRIPTION OF THE DRAWINGS

FIG. 1A is a schematic diagram of an example embodiment of the timing circuitry of the latch of the present invention.

FIG. 1B is a schematic diagram of an example embodiment of the latch of the present invention that is controlled by timing signals received from the timing circuitry schematically illustrated in FIG. 1A.

FIG. 2 is a timing diagram illustrating the manner in which the latch shown in FIG. 1B is controlled by the timing signals generated by the timing circuitry shown in FIG. 1A to enable the latch of FIG. 1B to be resistant to alpha strikes.

### DETAILED DESCRIPTION OF THE INVENTION

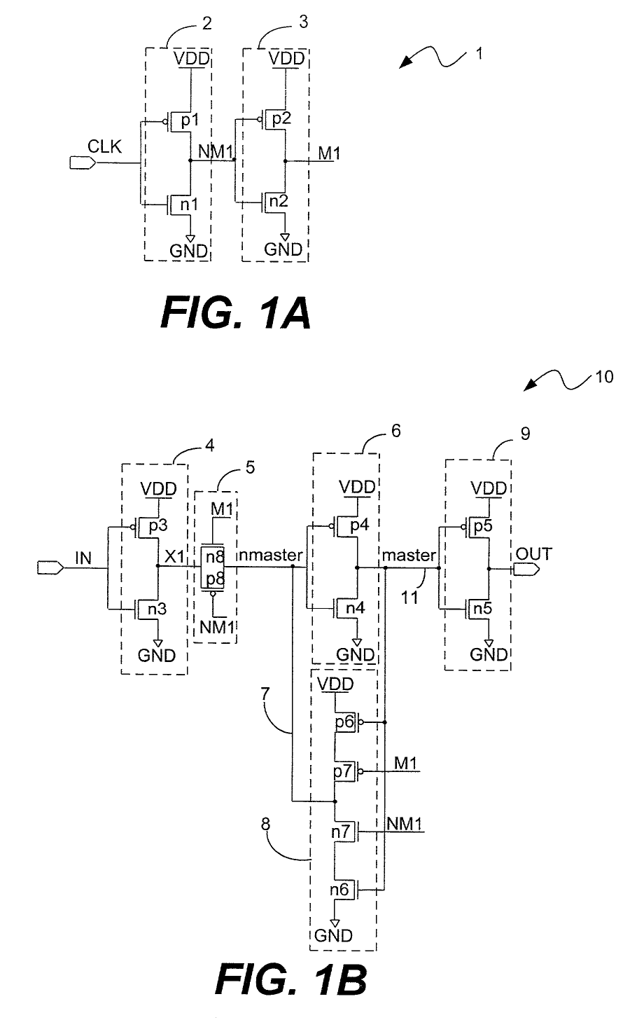

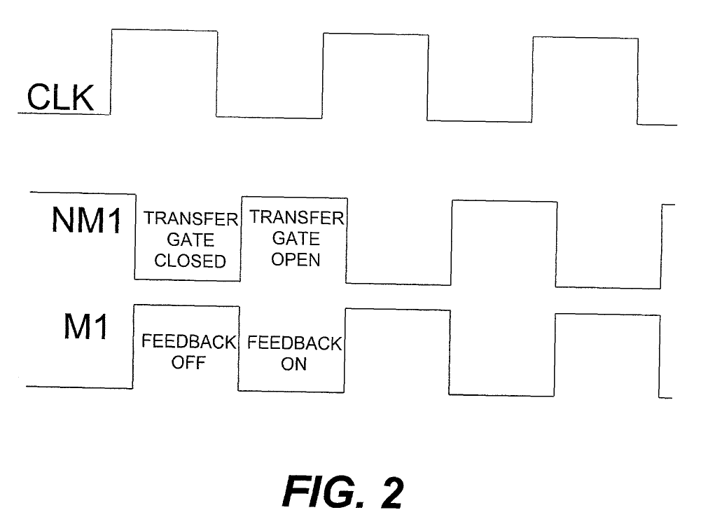

In accordance with the present invention, a feedback circuit is used in the latch to drive the storage node of the latch with enough strength to prevent an error from occurring when an alpha strike occurs. However, in contrast to the prior art designs that utilize feedback to prevent errors from occurring due to alpha strikes, the feedback circuit of the latch of the present invention is turned off when the input circuitry of the latch is driving the latch. In accordance with the present invention, it has been determined that the latch input circuitry is strong enough to prevent an alpha strike error from occurring when the input circuitry is driving the latch. An input transfer gate of the latch is closed when the input circuitry is driving the latch. When the input transfer gate is closed, the drive strength of the input circuitry is great enough to prevent the occurrence of an alpha strike error. Whenever the input transfer gate of the latch is open (i.e., when the input circuitry is not driving the latch), the feedback circuit is turned on to prevent the occurrence of an alpha strike error. This “gated feedback” feature of the present invention enables a smaller latch design to be employed while keeping the setup time of the latch at a minimum. The manner in which this is accomplished will now be discussed with reference to the schematic diagrams FIGS. 1A and 1B and with respect to the timing diagram of FIG. 2.

FIG. 1A is a schematic diagram of a timing circuit 1 that receives the clock signal, CLK, that controls the timing of storing data in and outputting data from the latch 10 of FIG. 1B. The timing circuit 1 is comprised of a first inverter 2 and a second inverter 3. The first inverter 2 includes a p field effect transistor (hereinafter referred to as “pFET”), p1, and an n field effect transistor (hereinafter referred to as “nFET”), n1 that are connected to each other in series. The pFET p1 and the nFET n2 simultaneously receive the clock signal, CLK, at their gates. The second inverter 3 includes a pFET, p2, and an nFET, n2 that are connected to each other in series. The pFET p2 and the nFET n2 simultaneously receive the inverted clock signal, NM1, at their gates. The second inverter 3 then inverts NM1 to obtain M1, which has the same value as the clock signal received at the gates of pFET p1 and nFET n1. Therefore, NM1 corresponds to the inverted clock signal and M1 corresponds to the clock signal, as shown in FIG. 2. Of course, the inverters 2 and 3 take a small amount of time to change their values and are therefore shown in FIG. 2 as being slightly time-shifted with respect to the clock signal, CLK. The relationships between the signals CLK, M1 and NM1 is shown in FIG. 2.

FIG. 1B is a schematic diagram of a latch 10 that has been designed in accordance with an embodiment of the present invention. The gating of the feedback of the latch 10 is controlled by the values of NM1 and M1 produced by the timing circuit 1 in response to the clock signal, CLK. The input circuitry of the latch 1 is comprised of the inverter 4, which includes a pFET, p3, connected in series with an nFET, n3. The inverter 4 is followed by a transfer gate 5 that includes an nFET, n8, connected in parallel with a pFET, p8. Whenever the clock signal CLK is high, NM1 is low and M1 is high. Therefore, whenever the clock signal is high, the transfer gate 5 will be closed because the signal M1 is received at the gate of the nFET n8 and the signal NM1 is received at the gate of the pFET p8. When the transfer gate 5 is closed, a resistive connection exists between the sources and drains of nFET n8 and pFET p8, which are connected in parallel. This resistive connection allows the signal X1 to pass through the transfer gate 5 to the input of the inverter 6. Therefore, when the clock signal is high, the inverted value X1 of the signal input to the latch, IN, will be transferred to the input of inverter 6.

When CLK is low, the feedback circuit 8 will drive the latch 10. When CLK is high, M1 is high and NM1 is low, and these signals are being received at the gates of pFET p7 and nFET n7, respectively, which will place these transistors in their non-conductive states. However, when CLK is low, pFET p7 and nFET n7 will be placed and their conductive states and the feedback signal connection 7 will be pulled to the opposite value of the master node 11. Thus, whenever the clock signal is low, the transfer gate 5 will be opened and the feedback circuit 8 will provide a strong feedback signal that will prevent an alpha strike error from occurring. In other words, whenever the input circuitry 4 of the latch 10 is not driving the latch 10, the feedback signal connection 7 will prevent the value of the signal “nmaster” from changing because the feedback circuit 8 will ensure that the value of “nmaster” is the inverted value of the signal “master” via the connection of the signal “master” to the gate of nFET n6.

When the transfer gate 5 is closed, the signal “nmaster” will be inverted by inverter 6 into the signal “master”, which will then be inverted by the inverter 9 into the output signal, “OUT”, of the latch 10. The signal “OUT” will have the opposite state as the signal “IN”. The state of the signal “OUT” will remain the inverted value of the signal “master” as long as the feedback signal connection 7 is driving the input of inverter 6 (i.e., whenever the input circuitry 4 of the latch 10 is not driving the latch 10).

It should be noted that the particular logical configuration shown in FIGS. 1A and 1B is only one example of the manner in which the present invention could be implemented. Those skilled in the art will understand, in view of the discussion provided herein, that many different logical configurations may be used to accomplish the goals of the present invention, namely, of providing a strong feedback that overcomes the possible results of an alpha strike only when the input circuitry of the latch is not driving the latch. For example, additional logic could be added to the circuits shown in FIGS. 1A and 1B without necessarily changing the operations thereof or defeating its goals. Increases in logical complexity are sometimes made for various reasons, such as to further enhance performance, or to allow certain types of tests to be performed. Also, it should be noted that the input circuitry 4 of the latch 10 could be located outside of the latch 10 as part of some other circuitry that drives the latch 10.

Also, although field effect transistor logic is shown in the example embodiments, those skilled in the art will understand that other types of transistor technology may be used to construct a latch in accordance with the present invention. The particular field effect transistor technology demonstrated in the example embodiment corresponds to a low-voltage fabrication process and is used to demonstrate that the goals of the present invention can be accomplished even when such a process is used. However, it should be noted that this is merely an advantage of the present invention and not a limitation. The advantages of present invention may also be realized when fabrication processes that are not viewed as “low-voltage processes” are used to fabricate the latch.

Also, as indicated above, the present invention is not limited to latch designs, but also extends to other logical configurations that may be detrimentally affected by alpha strikes, such as register designs, which typically include a plurality of latches. Those skilled in the art will understand the manner in which the feedback circuit and transfer gate concepts (i.e., the gated feedback) of the present invention can be used with such other logical implementations. Those skilled in the art will understand that other modifications may be made to the embodiments discussed herein that are also within the scope of the present invention.

What is claimed is:

1. A latch comprising:
input circuitry configured to receive an input data value to be stored in the latch;
a transfer gate configured to be opened and closed, wherein when the transfer gate is closed, a signal associated with said input data value is allowed to pass through the transfer gate and to be stored in the latch;
a feedback circuit configured to be turned on and off, wherein when said input circuitry is driving the latch, the transfer gate is closed and the feedback circuit is turned off, wherein when the latch is being driven by the input circuitry, the latch is resistant to an alpha strike, and wherein when the latch is not being driven by the input circuitry, the transfer gate is opened and the feedback circuit is turned on, wherein when the feedback circuit is turned on, the feedback circuit generates a feedback signal that drives the latch and renders the latch resistant to an alpha strike.

2. The latch of claim 1, wherein the latch is comprised of field effect transistor (FET) technology elements.

3. The latch of claim 1, wherein the input circuitry comprises a p field effect transistor (pFET) connected in series with an n field effect transistor (nFET), and wherein the pFET and nFET are sufficiently large such that when the input circuitry is driving the latch, the latch is resistant to an alpha strike.

4. The latch of claim 1, wherein the feedback circuit includes a plurality of p field effect transistors (pFETs) connected in series, and a plurality of n field effect transistors (nFETs) connected in series.

5. The latch of claim 1, wherein the feedback circuit comprises an inverter having an input and an output, and wherein when the transfer gate is closed, the feedback circuit is turned on and the inverter of the feedback circuit inverts the signal associated with said input data value and feeds the inverted signal back to the input of the inverter of the feedback circuit, and wherein the strength of the signal feedback to the input of the inverter of the feedback circuit is sufficient to prevent an alpha strike error from occurring in the latch.

6. The latch of claim 1, wherein the transfer gate comprises a p field effect transistor having a gate, a source and a drain and an n field effect transistor having a gate, a source and a drain, the sources and drains of the transistors being connected to each other, and wherein the transfer gate is closed by creating a resistive connection between the sources and drains of the transistors that allows the signal associated with the input data value to pass through the transfer gate to an input of an inverter of the feedback circuit, and wherein the inverter of the feedback circuit inverts said signal and feeds the inverted signal back to the input of the inverter of the feedback circuit when the transfer gate is opened.

7. The latch of claim 6, wherein the transistors are placed in a conductive state by applying a High signal to the nFET and a Low signal to the pFET, the High and Low signals being derived from a clock signal.

8. The latch of claim 6, further comprising output circuitry, the output circuitry comprising an inverter having an input and an output, wherein the inverter of the output circuitry re-inverts said inverted signal.

9. The latch of claim 6, wherein the input circuitry, the transfer gate and the output circuitry are constructed of field effect transistors (FETs).

10. The latch of claim 6, wherein the latch is constructed using a low-voltage complementary metal oxide semiconductor (CMOS) fabrication process.

11. The latch of claim 8, wherein each of the inverters comprises a p field effect transistor (pFET) connected in series with an n field effect transistor (nFET).

12. The latch of claim 1, wherein the transfer gate is closed by sending at least one signal to the transfer gate that causes a conductive connection to be made between the input circuitry and a storage node of the latch, said at least one signal sent to the transfer gate being derived from a clock signal.

13. The latch of claim 12, wherein the transfer gate comprises a p field effect transistor having a gate, a source and a drain and an n field effect transistor having a gate, a source and a drain, the sources and drains of the transistors being connected to each other, and wherein said at least one signal includes a High signal and a Low signal, the gate of the n field effect transistor receiving the High signal and the gate of the p field effect transistor receiving the Low signal, wherein the receipt of the High and Low signals by the gates of the n field effect transistor and the p field effect transistor, respectively, causes a resistive connection to be created between the sources and drains of the transistors, which creates the conductive connection between the input circuitry and the storage node of the latch.

14. The latch of claim 1, wherein the transfer gate is opened by sending at least one signal to the transfer gate that prevents a conductive connection from being made between the input circuitry and a storage node of the latch, said at least one signal sent to the transfer gate being derived from a clock signal.

15. The latch of claim 14, wherein the transfer gate comprises a p field effect transistor having a gate, a source and a drain and an n field effect transistor having a gate, a source and a drain, the sources and drains of the transistors being connected to each other, and wherein said at least one signal includes a High signal and a Low signal, the gate of the n field effect transistor receiving the Low signal and the gate of the p field effect transistor receiving the High signal, wherein the receipt of the Low and High signals by the gates of the n field effect transistor and the p field effect transistor, respectively, prevents a resistive connection from being created between the sources and drains of the transistors, which prevents the conductive connection between the input circuitry and the storage node of the latch from being created, thereby causing the transfer gate to be opened.

16. The latch of claim 15, wherein the feedback circuit comprises a p field effect transistor having a gate, a source and a drain and an n field effect transistor having a gate, a source and a drain, the sources and drains of the transistors being connected to each other, and wherein the High and Low signals sent to the gates of the p and n field effect transistors of the transfer gate, respectively, are substantially simultaneously sent to the gates of the n and p field effect transistors of the feedback circuit, respectively, and wherein receipt of the High and Low signals at the gates of the n and p field effect transistors of the feedback circuit, respectively, causes the feedback circuit to be turned on and the feedback signal to be generated.

17. A method of storing data in a latch that renders the latch resistant to alpha strikes and prevents the stored data from being corrupted, the method comprising the steps of:
receiving an input data value to be stored in the latch;
closing a transfer gate when the input data value to be stored in the latch is received at input circuitry of the latch, wherein while the transfer is closed, the input circuitry drives the latch with sufficient strength to prevent an alpha strike error from occurring in the latch;
opening the transfer gate once the input data value has been stored in the latch and turning on a feedback circuit that generates a feedback signal that drives the latch and renders the latch resistant to an alpha strike while the transfer gate is open.

18. The method of claim 17, wherein the step of closing the transfer gate includes sending at least one signal to the transfer gate that causes a conductive connection to be made between the input circuitry and a storage node of the latch, said at least one signal sent to the transfer gate being derived from a clock signal.

19. The method of claim 18, wherein the transfer gate comprises a p field effect transistor having a gate, a source and a drain and an n field effect transistor having a gate, a source and a drain, the sources and drains of the transistors being connected to each other, and wherein said at least one signal includes a High signal and a Low signal, the gate of the n field effect transistor receiving the High signal and the gate of the p field effect transistor receiving the Low signal, wherein the receipt of the High and Low signals by the gates n field effect transistor and the p field effect transistor, respectively, causes a resistive connection to be created between the sources and drains of the transistors, which creates the conductive connection between the input circuitry and the storage node of the latch.

20. The method of claim 17, wherein the step of opening the transfer gate includes sending at least one signal to the transfer gate that prevents a conductive connection from being made between the input circuitry and a storage node of the latch, said at least one signal sent to the transfer gate being derived from a clock signal.

21. The method of claim 20, wherein the transfer gate comprises a p field effect transistor having a gate, a source and a drain and an n field effect transistor having a gate, a source and a drain, the sources and drains of the transistors being connected to each other, and wherein said at least one signal includes a High signal and a Low signal, the gate of the n field effect transistor receiving the Low signal and the gate of the p field effect transistor receiving the High signal, wherein the receipt of the Low and High signals by the gates of the n field effect transistor and the p field effect transistor, respectively, prevents a resistive connection from being created between the sources and drains of the transistors, which prevents the conductive connection between the input circuitry and the storage node of the latch from being created, thereby causing the transfer gate to be opened.

22. The method of claim 21, wherein the feedback circuit comprises a p field effect transistor having a gate, a source and a drain and an n field effect transistor having a gate, a source and a drain, the sources and drains of the transistors being connected to each other, and wherein the High and Low signals sent to the gates of the p and n field effect transistors of the transfer gate, respectively, are substantially simultaneously sent to the gates of the n and p field effect transistors of the feedback circuit, respectively, and wherein receipt of the High and Low signals at the gates of the n and p field effect transistors of the feedback circuit, respectively, cause the feedback circuit to be turned on and the feedback signal to be generated.
